(19) United States
(12) Patent Application Publication
(10) Pub. No.: US 2025/0386471 A1
(43) Pub. Date: Dec. 18, 2025

(54) LIQUID-COOLING COOLER FOR POWER MODULE OF ELECTRIC VEHICLE

(71) Applicant: AMULAIRE THERMAL TECHNOLOGY, INC., New Taipei City (TW)

(72) Inventors: CHING-MING YANG, New Taipei City (TW); KUO-WEI LEE, New Taipei City (TW); TZE-YANG YEH, New Taipei City (TW); CHIEN-CHENG WU, New Taipei City (TW); CHUN-LUNG WU, New Taipei City (TW); YI-HSIN HUANG, New Taipei City (TW); MING-HSUAN CHANG, Taoyuan City (TW)

(21) Appl. No.: 18/743,667

(22) Filed: Jun. 14, 2024

(51) Int. Cl. H05K 7/20

(52) U.S. Cl. CPC H05K 7/20872; H05K 7/20263

(57) ABSTRACT

A liquid-cooling cooler for an electric vehicle power module includes an inlet end, an outlet end, and a chamber connected to the inlet end and the outlet end. A plurality of fin regions arranged in a water flow direction are located within the chamber. The plurality of fin regions include at least one high-density fin region, such that at least one low-density and inlet-end-adjacent fin region is more adjacent to the inlet end and is of lower density than the at least one high-density fin region, and at least one low-density and outlet-end-adjacent fin region is more adjacent to the outlet end and is of lower density than the at least one high-density fin region. The plurality of fin regions include at least one low-density fin region.

### FIELD OF THE DISCLOSURE

The present disclosure relates to a liquid-cooling cooler, and more particularly to a liquid-cooling cooler for an electric vehicle power module.

### BACKGROUND OF THE DISCLOSURE

Currently, commercially available EV power modules such as an insulated gate bipolar transistor (IGBT) module or an advanced driver assistance system (ADAS) module has an increasing number of chips and regions that require heat-dissipation, such that existing liquid-cooling coolers are unable to meet the heat-dissipation requirements of the EV power modules. Therefore, how to more effectively dissipate heat through liquid-cooling cooling technology has been an issue to be addressed in the relevant industry.

### SUMMARY OF THE DISCLOSURE

In response to the above-referenced technical inadequacies, the present disclosure provides a liquid-cooling cooler for an electric vehicle power module.

In order to solve the above-mentioned problems, one of the technical aspects adopted by the present disclosure is to provide a liquid-cooling cooler for an electric vehicle power module adapted for contacting multiple heat sources of the electric vehicle power module, and the liquid-cooling cooler includes an inlet end, an outlet end, and a chamber connected to the inlet end and the outlet end. A plurality of fin regions arranged in a water flow direction are located within the chamber. The plurality of fin regions include at least one high-density fin region, such that at least one low-density and inlet-end-adjacent fin region is more adjacent to the inlet end and is of lower density than the at least one high-density fin region, and at least one low-density and outlet-end-adjacent fin region is more adjacent to the outlet end and is of lower density than the at least one high-density fin region. The plurality of fin regions include at least one low-density fin region, such that at least one high-density and inlet-end-adjacent fin region is more adjacent to the inlet end and is of higher density than the at least one low-density fin region, and at least one high-density and outlet-end-adjacent fin region is more adjacent to the outlet end and is of higher density than the at least one low-density fin region.

In one of the possible or preferred embodiments, the at least one high-density fin region is one of the high-density and inlet-end-adjacent fin region and the high-density and outlet-end-adjacent fin region.

In one of the possible or preferred embodiments, the at least one low-density fin region is one of the low-density and inlet-end-adjacent fin region and the low-density and outlet-end-adjacent fin region.

In one of the possible or preferred embodiments, a density of each of the fin regions is defined as, in each of the fin regions, a total surface area of fins calculated for a maximum identical number of adjacent fins having a same distance from each other being divided by a total fin projection area.

In one of the possible or preferred embodiments, the chamber is formed by a plate and a cover that covers the plate, and the plate and the cover are formed by metal injection molding, forging, or stamping.

In one of the possible or preferred embodiments, the plate and the cover are made of copper, copper alloy, aluminum, or aluminum alloy.

In one of the possible or preferred embodiments, each of the fin regions has a different fin cross-sectional shape from an adjacent different one of the fin regions.

In one of the possible or preferred embodiments, each of the fin regions has a different fin height from an adjacent different one of the fin regions.

In one of the possible or preferred embodiments, each of the fin regions has a different fin distance from an adjacent different one of the fin regions.

In one of the possible or preferred embodiments, each of the fin regions has a different average radius of fins from an adjacent different one of the fin regions.

In one of the possible or preferred embodiments, a maximum density ratio of the high-density fin region to the low-density and inlet-end-adjacent fin region is configured to be from 1.1 to 1.6.

In one of the possible or preferred embodiments, a maximum density ratio of the high-density fin region to the low-density and outlet-end-adjacent fin region is configured to be from 1.1 to 1.6.

In one of the possible or preferred embodiments, a maximum density ratio of the low-density fin region to the high-density and inlet-end-adjacent fin region is configured to be from 0.6 to 0.9.

In one of the possible or preferred embodiments, a maximum density ratio of the low-density fin region to the high-density and outlet-end-adjacent fin region is configured to be from 0.6 to 0.9.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of fin regions according to a first embodiment of the present disclosure;

FIG. 2 is a schematic top view of the fin regions according to the first embodiment of the present disclosure;

FIG. 3 is a schematic view of a fin according to the first embodiment of the present disclosure;

FIG. 4 is a schematic view of fin projection areas according to the first embodiment of the present disclosure;

FIG. 5 is a schematic top view of fin regions according to a second embodiment of the present disclosure;

FIG. 6 is a schematic top view of fin regions according to a third embodiment of the present disclosure;

FIG. 7 is a schematic top view of fin regions according to a fourth embodiment of the present disclosure;

FIG. 8 is a schematic top view of fin regions according to a fifth embodiment of the present disclosure; and

FIG. 9 is a schematic top view of fin regions according to a sixth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

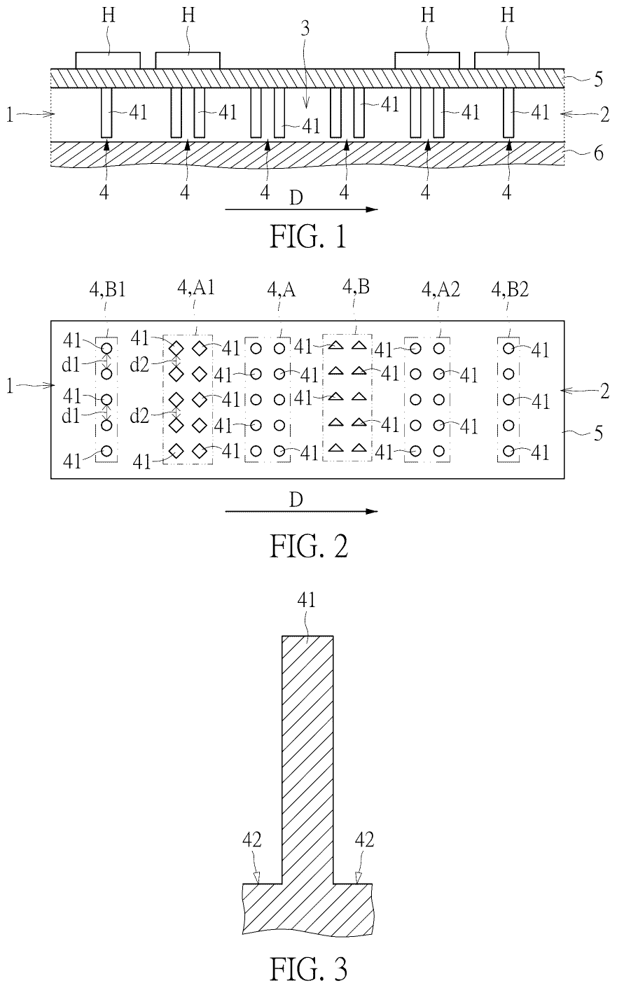

Referring to FIG. 1 to FIG. 4, a first embodiment of the present disclosure provides a liquid-cooling cooler for an electric vehicle power module adapted for contacting multiple heat sources H of the electric vehicle power module. Each of the heat sources H can be a chip, a direct bonded copper ceramic (DBC) substrate having a chip, or an active metal brazing (AMB) ceramic substrate having a chip, and the electric vehicle power module can be an insulated gate bipolar transistor (IGBT) module or an automotive advanced driver assistance system (ADAS) module. The liquid-cooling cooler for the electric vehicle power module includes an inlet end 1, an outlet end 2, and a chamber 3 connected to the inlet end 1 and the outlet end 2, and a plurality of fin regions 4 arranged in a water flow direction D are located within the chamber 3.

In this embodiment, six or more fin regions 4 are provided in the chamber 3, and the fin regions 4 include at least one high-density fin region A as shown in FIG. 2, such that at least one low-density and inlet-end-adjacent fin region B1 is more adjacent to the inlet end 1 and is of lower density than the high-density fin region A, and at least one low-density and outlet-end-adjacent fin region B2 is more adjacent to the outlet end 2 and is of lower density than the high-density fin region A. Moreover, the fin regions 4 include at least one low-density fin region B, such that at least one high-density and inlet-end-adjacent fin region A1 is more adjacent to the inlet end 1 and is of higher density than the low-density fin region B, and at least one high-density and outlet-end-adjacent fin region A2 is more adjacent to the outlet end 2 and is of higher density than the low-density fin region B. In this way, heat dissipation can be performed for the heat sources H of the electric vehicle power module and the overall heat dissipation temperature can be uniform.

Further, the density of each of the above-mentioned fin regions 4 is defined as, in each of the fin regions 4, a total surface area of fins 41 calculated for a maximum identical number of adjacent fins 41 having a same distance from each other being divided by a total fin projection area. For example, as shown in FIG. 2, the low-density and inlet-end-adjacent fin region B1 includes a maximum of five adjacent fins 41 having the same distance d1 from each other to calculate a density; when the density of the high-density and inlet-end-adjacent fin region A1 needs to be calculated for comparison, the density of the high-density and inlet-end-adjacent fin region A1 is also calculated by taking five neighboring fins 41 having a same distance d2 from each other and located in the high-density and inlet-end-adjacent fin region A1, even though there may be ten adjacent fins 41 having the same distance d2 from each other in the high-density and inlet-end-adjacent fin region A1. The distance d1 and the distance d2 may be different. In addition, a minimal distance between one of the fins 41 and an adjacent one of the fins 41 in each of the fin regions 4 is the distance referred to herein.

Further, as shown in FIGS. 2 and 3, the total surface area of the fins 41 of the low-density and inlet-end-adjacent fin region B1 is defined as a total surface area of five adjacent fins 41 having the same distance d1 from each other, and an area of parts of the bottom surface 42 within the low-density and inlet-end-adjacent fin region B1 not occupied by the five adjacent fins 41. The total surface area of the fins in the high-density and inlet-end-adjacent fin region A1 and the total surface area of the fins in other fin regions are calculated in the same manner.

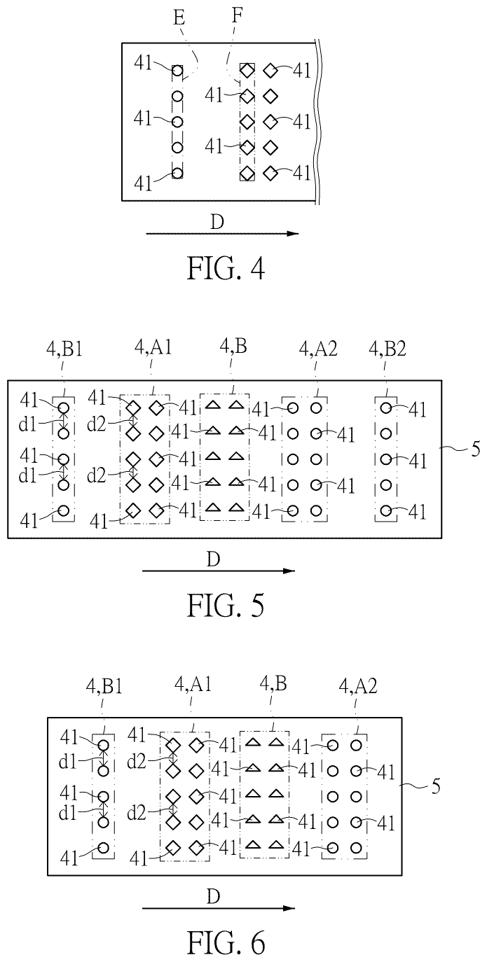

A fin projection area E (as shown in FIG. 4) of the low-density and inlet-end-adjacent fin region B1 is defined as the smallest rectangular projection area that can enclose up to the highest quantity of identical fins in the fin region B1, and a fin projection area F (as shown in FIG. 4) of the high-density and inlet-end-adjacent fin region A1 is also defined as the smallest rectangular projection area that can enclose up to the highest quantity of identical fins in the fin region A1. The fin projection area of other fin regions is calculated in the same manner.

Furthermore, in order to have a more uniformed overall heat dissipation temperature, a maximum density ratio of the high-density fin region A to the low-density and inlet-end-adjacent fin region B1 is configured to be from 1.1 to 1.6, and a maximum density ratio of the high-density fin region A to the low-density and outlet-end-adjacent fin region B2 is configured to be from 1.1 to 1.6. In addition, a maximum density ratio of the low-density fin region B to the high-density and inlet-end-adjacent fin region A1 is configured to be from 0.6 to 0.9, and a maximum density ratio of the low-density fin region B to the high-density and outlet-end-adjacent fin region A2 is configured to be from 0.6 to 0.9.

In this embodiment, each of the fin regions 4 may have a different fin cross-sectional shape from an adjacent different one of the fin regions 4.

In this embodiment, the chamber 3 of the liquid-cooling cooler of the electric vehicle power module can be formed by a plate 5 and a cover 6 that covers the plate 5, and the plate 5 and the cover 6 can be formed by metal injection molding, forging, or stamping. In addition, the fins 41 in each of the fin regions 4 may be formed integrally with the plate 5. Furthermore, the plate 5 and the cover 6 may be made of copper, copper alloy, aluminum, or aluminum alloy.

### Second Embodiment

Referring to FIG. 5, FIG. 5 shows a second embodiment of the present disclosure. This embodiment is substantially the same as the first embodiment, and the differences therebetween are described below.

In this embodiment, the plate 5 has five or more fin regions 4 arranged along the water flow direction D. That is, the high-density fin region A as shown in FIG. 2 of the first embodiment can be the high-density and inlet-end-adjacent fin region A1 of this embodiment, and can alternatively be the high-density and outlet-end-adjacent fin region A2.

### Third Embodiment

Referring to FIG. 6, FIG. 6 shows a third embodiment of the present disclosure. This embodiment is substantially the same as the first embodiment, and the differences therebetween are described below.

In this embodiment, the plate 5 has four or more fin regions 4 arranged along the water flow direction D. That is, the high-density fin region A as shown in FIG. 2 of the first embodiment can be the high-density and inlet-end-adjacent fin region A1 of this embodiment. In addition, in this embodiment, with respect to the high-density and outlet-end-adjacent fin region A2, the low-density fin region B can be a low-density and outlet-end-adjacent fin region.

### Fourth Embodiment

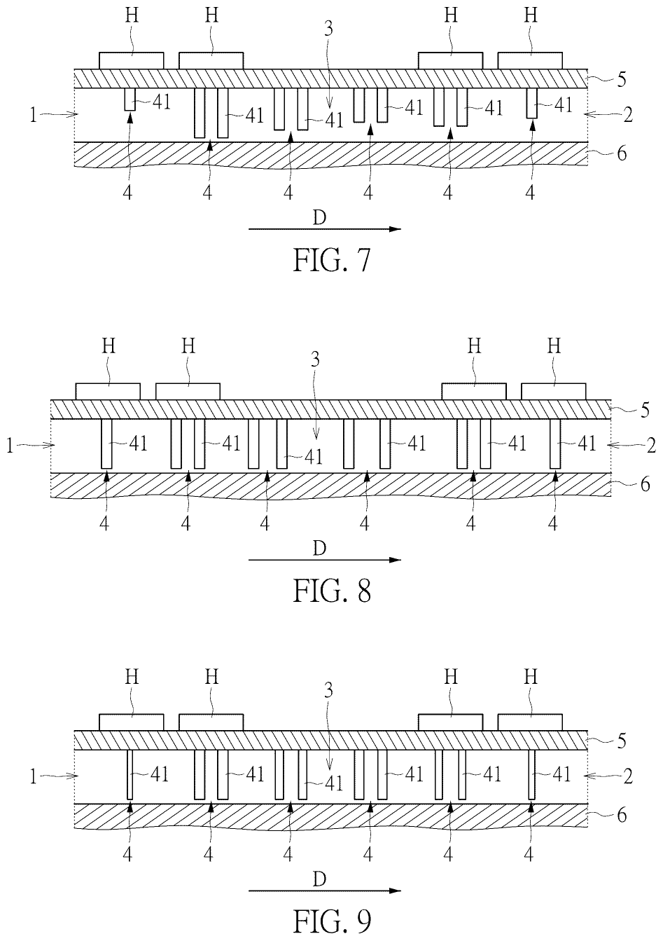

Referring to FIG. 7, FIG. 7 shows a fourth embodiment of the present disclosure. This embodiment is substantially the same as the first embodiment, and the differences therebetween are described below.

In this embodiment, each of the fin regions 4 may have a different fin height from an adjacent different one of the fin regions 4. The fin height referred to herein is a length from a bottom surface on which the fins 41 are located to top portions of the fins 41; in other words, the fin height is a normal length of each of the fins 41 relative to the bottom surface on which the fins 41 are located.

### Fifth Embodiment

Referring to FIG. 8, FIG. 8 shows a fifth embodiment of the present disclosure. This embodiment is substantially the same as the first embodiment, and the differences therebetween are described below.

In this embodiment, each of the fin regions 4 may have a different fin distance from an adjacent different one of the fin regions 4. The fin distance referred to herein is a shortest distance between one of the fins 41 and an adjacent one of the fins 41.

### Sixth Embodiment

Referring to FIG. 9, FIG. 9 shows a sixth embodiment of the present disclosure. This embodiment is substantially the same as the first embodiment, and the differences therebetween are described below.

In this embodiment, each of the fin regions 4 may have a different average radius of fins from an adjacent different one of the fin regions 4. The average radius of fins referred to herein is a value of a square root of the cross-sectional area of each of the fins 41 divided by T.

### Beneficial Effects of the Embodiments

In summary, the present disclosure provides a liquid-cooling cooler for an electric vehicle power module adapted for contacting multiple heat sources of the electric vehicle power module, and the liquid-cooling cooler includes an inlet end, an outlet end, and a chamber connected to the inlet end and the outlet end. A plurality of fin regions arranged in a water flow direction are located within the chamber. The plurality of fin regions include at least one high-density fin region, such that at least one low-density and inlet-end-adjacent fin region is more adjacent to the inlet end and is of lower density than the at least one high-density fin region, and at least one low-density and outlet-end-adjacent fin region is more adjacent to the outlet end and is of lower density than the at least one high-density fin region. The plurality of fin regions include at least one low-density fin region, such that at least one high-density and inlet-end-adjacent fin region is more adjacent to the inlet end and is of higher density than the at least one low-density fin region, and at least one high-density and outlet-end-adjacent fin region is more adjacent to the outlet end and is of higher density than the at least one low-density fin region. In this way, heat dissipation can be performed for the heat sources of the electric vehicle power module and the overall heat dissipation temperature can be uniform.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling cooler for an electric vehicle power module adapted for contacting multiple heat sources of the electric vehicle power module, and the liquid-cooling cooler comprising an inlet end, an outlet end, and a chamber connected to the inlet end and the outlet end, wherein a plurality of fin regions arranged in a water flow direction are located within the chamber;
wherein the plurality of fin regions include at least one high-density fin region, such that at least one low-density and inlet-end-adjacent fin region is more adjacent to the inlet end and is of lower density than the at least one high-density fin region, and at least one low-density and outlet-end-adjacent fin region is more adjacent to the outlet end and is of lower density than the at least one high-density fin region;
wherein the plurality of fin regions include at least one low-density fin region, such that at least one high-density and inlet-end-adjacent fin region is more adjacent to the inlet end and is of higher density than the at least one low-density fin region, and at least one high-density and outlet-end-adjacent fin region is more adjacent to the outlet end and is of higher density than the at least one low-density fin region.

2. The liquid-cooling cooler according to claim 1, wherein the at least one high-density fin region is one of the high-density and inlet-end-adjacent fin region and the high-density and outlet-end-adjacent fin region.

3. The liquid-cooling cooler according to claim 1, wherein the at least one low-density fin region is one of the low-density and inlet-end-adjacent fin region and the low-density and outlet-end-adjacent fin region.

4. The liquid-cooling cooler according to claim 1, wherein a density of each of the fin regions is defined as, in each of the fin regions, a total surface area of fins calculated for a maximum identical number of adjacent fins having a same distance from each other being divided by a total fin projection area.

5. The liquid-cooling cooler according to claim 1, wherein the chamber is formed by a plate and a cover that covers the plate, and the plate and the cover are formed by metal injection molding, forging, or stamping.

6. The liquid-cooling cooler according to claim 5, wherein the plate and the cover are made of copper, copper alloy, aluminum, or aluminum alloy.

7. The liquid-cooling cooler according to claim 1, wherein each of the fin regions has a different fin cross-sectional shape from an adjacent different one of the fin regions.

8. The liquid-cooling cooler according to claim 1, wherein each of the fin regions has a different fin height from an adjacent different one of the fin regions.

9. The liquid-cooling cooler according to claim 1, wherein each of the fin regions has a different fin distance from an adjacent different one of the fin regions.

10. The liquid-cooling cooler according to claim 1, wherein each of the fin regions has a different average radius of fins from an adjacent different one of the fin regions.

11. The liquid-cooling cooler according to claim 1, wherein a maximum density ratio of the high-density fin region to the low-density and inlet-end-adjacent fin region is configured to be from 1.1 to 1.6.

12. The liquid-cooling cooler according to claim 1, wherein a maximum density ratio of the high-density fin region to the low-density and outlet-end-adjacent fin region is configured to be from 1.1 to 1.6.

13. The liquid-cooling cooler according to claim 1, wherein a maximum density ratio of the low-density fin region to the high-density and inlet-end-adjacent fin region is configured to be from 0.6 to 0.9.

14. The liquid-cooling cooler according to claim 1, wherein a maximum density ratio of the low-density fin region to the high-density and outlet-end-adjacent fin region is configured to be from 0.6 to 0.9.
